(19) United States
(12) Patent Application Publication
(10) Pub. No.: US 2025/0344358 A1
(43) Pub. Date: Nov. 6, 2025

(54) POWER ELECTRONIC SYSTEM HAVING A CAPACITOR DEVICE AND A THERMALLY COUPLED COOLING DEVICE

(71) Applicant: Semikron Danfoss Elektronik GmbH & Co. KG, Nürnberg (DE)

(72) Inventors: Sandro Bulovic, Langenzenn (DE); Johannes Klier, Amberg (DE); Christian Zeiler, Pommersfelden (DE); Pacomius Kutschera, Erlangen (DE)

(21) Appl. No.: 19/194,154

(22) Filed: Apr. 30, 2025

(30) Foreign Application Priority Data
May 2, 2024 (DE) 102024112358.3

(51) Int. Cl. H05K 7/20; H01G 2/08; H01G 4/224; H01G 4/40

(52) U.S. Cl. CPC H05K 7/209; H01G 2/08; H01G 4/224; H01G 4/40; H05K 7/20927

(57) ABSTRACT

A power electronic system is described, having a capacitor device and having a cooling device, wherein the cooling device has a first cooling contact surface with a normal direction, which is in direct thermal contact with the capacitor device, wherein the capacitor device has a first and a second element connecting device.

### CROSS-REFERENCE TO RELATED APPLICATION

This application claims foreign priority benefits under 35 U.S.C. § 119 to German Patent Application No. 102024112358.3 filed on May 2, 2024, the content of which is hereby incorporated by reference in its entirety.

### TECHNICAL FIELD

The invention relates to a power electronic system having a capacitor device and having a cooling device, wherein the cooling device has a first cooling contact surface with a normal direction, which is in thermal contact with the capacitor device, wherein the capacitor device has a first and a second element connecting device.

### BACKGROUND

DE 10 2019 134 650 A1 discloses a power electronic system having a housing, having a cooling device, having a power semiconductor module and having a capacitor device, wherein a cooling section of a capacitor connection device is in thermally conductive contact with a cooling surface of the cooling device.

DE 10 2012 215 787 A1 discloses a power electronic system having a multi-part housing, a plurality of power electronic switching devices, a capacitor device and a liquid cooling device. Here, the multi-part housing consists of three housing elements of cuboid basic structure, a central element and an upper and a lower cover element of the central element, which are arranged on opposite connection surfaces of the central element, wherein the housing has an inlet and an outlet port for a cooling liquid and at least one upper cooling chamber is formed between the central element and the upper cover element and at least two lower cooling chambers are formed between the central element and the lower cover element, wherein each cooling chamber has at least one cooling surface and wherein cooling liquid, which enters through the inlet port and exits through the outlet port, can flow through the cooling chambers and thus form the liquid cooling device.

### SUMMARY

The invention is based on the object of proposing a power electronic system in which the coupling of a capacitor device with a liquid cooling device is improved.

This object is achieved according to the invention by a power electronic system having a capacitor device and having a cooling device, wherein the cooling device has a first cooling contact surface with a normal direction, which is in direct thermal contact with the capacitor device, wherein the capacitor device has a first and a second element connecting device.

It is preferred if the first element connecting device has a first main section arranged perpendicular to the normal direction and preferably the second element connecting device also has a second main section arranged perpendicular to the normal direction, preferably directly adjacent to the first.

It may be advantageous if the cooling device has a cooling plate element which is preferably of flat design and the surface of which forms the first cooling contact surface.

It may also be preferred if the cooling plate element is formed in one piece with the cooling device.

It may be advantageous in this case if the capacitor device has a plurality of capacitor elements which are preferably arranged next to one another, preferably in a matrix-like manner, and which are connected in a circuit-oriented manner by means of the first and second element connecting devices. It may be advantageous here if the first and preferably also the second main section is arranged between the first cooling contact surface and the capacitor elements. In addition, it may be advantageous if an insulation device, which is preferably formed flat, is arranged, preferably exclusively, for electrical insulation between the first element connecting device and the first cooling contact surface.

In principle, it may be advantageous if the first cooling contact surface covers at least more than 70%, preferably more than 80% and in particular preferably more than 90% of the first main section.

It may also be preferred if an insulation device, which is preferably formed flat, is arranged, preferably exclusively, for electrical insulation between the capacitor elements and the first cooling contact surface. It may be preferred here if the cooling plate element covers more than 70%, preferably more than 80% and in particular preferably more than 90% of each individual capacitor element.

Furthermore, it may be advantageous if the capacitor device and the cooling device are arranged in a cup-shaped first partial housing. It may be advantageous here if the cup-shaped first partial housing is filled with an insulating agent until it reaches the cooling device and covers the capacitor device completely, wherein this insulating agent is preferably designed as a standard potting compound for capacitor devices in the art. It may be advantageous in particular if the cooling device is arranged up to a first height in the insulating agent. It may be advantageous here if the first height is greater than the thickness of the cooling plate element.

It may be fundamentally advantageous if the first element connecting device has an additional first terminal section and the second element connecting device has an additional second terminal section and these terminal sections are designed for supplying power to all capacitor elements.

It may also be preferred if the first element connecting device has an additional first module section and the second element connecting device has an additional second module section and these module sections are designed for supplying power to a power semiconductor module from the capacitor elements.

Finally, it may be advantageous if a power semiconductor module is arranged on a second cooling contact surface that is parallel to the first.

Of course, insofar as this is not excluded explicitly or per se or does not contradict the concept of the invention, the features or groups of features which are in each case mentioned in the singular may be present multiple times in the power electronic system according to the invention.

It is understood that the various embodiments of the invention can be realized individually or in any desired combinations, in order to achieve improvements. In particular, the features which are mentioned and explained above and in the following can be used not only in the specified combinations, but also in other combinations or alone, without departing from the scope of the present invention.

### BRIEF DESCRIPTION OF THE DRAWINGS

Further explanations of the invention, advantageous details and features are to be found in the following description of the exemplary embodiments of the invention, which are illustrated schematically in FIGS. 1 to 6, or of respective parts thereof.

FIG. 1 shows a schematic illustration of a first embodiment of a power electronic system according to the invention in an exploded illustration.

FIG. 2 shows a side view of this first embodiment.

FIG. 3 shows a side view of a second embodiment of a power electronic system according to the invention.

FIGS. 4 and 5 show three-dimensional sectional views of the first embodiment with a different number of components.

FIG. 6 shows a three-dimensional view of the first embodiment.

### DETAILED DESCRIPTION

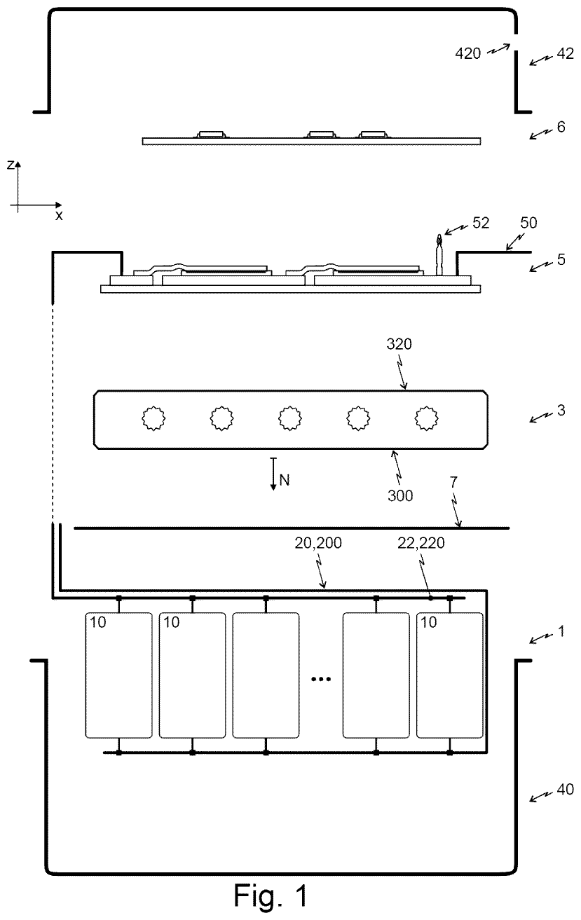

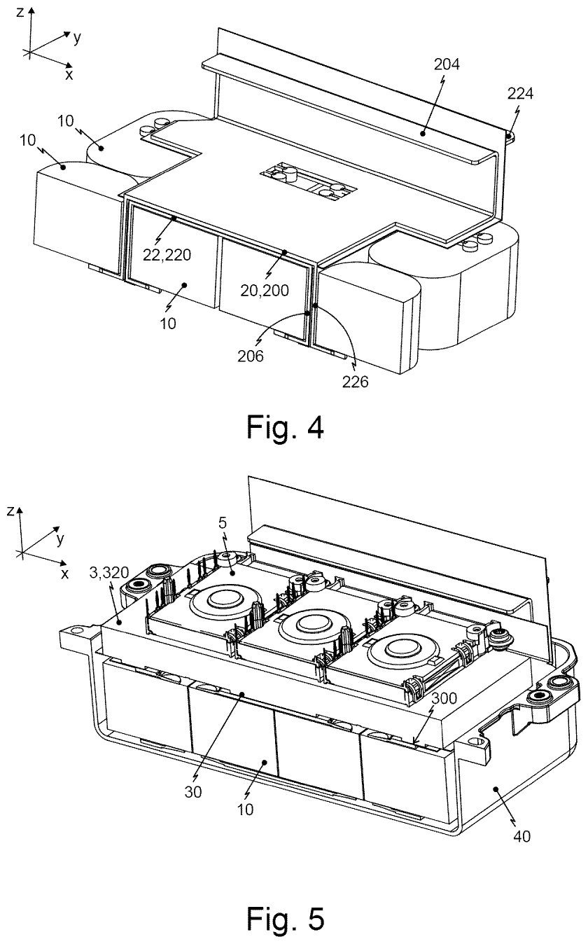

FIG. 1 shows a schematic illustration of a first embodiment of a power electronic system according to the invention in an exploded illustration. When observed from the bottom upwards, this system has an arrangement, which is stacked in a negative normal direction N, having a capacitor device 1, a cooling device 3, power switching equipment and control switching equipment 6. Here, the cooling device 3 has a first cooling contact surface 300 which defines the normal direction N and which is in direct thermal contact with the capacitor device 1. The capacitor device 1 has a plurality of individual capacitor elements 10 which are connected to one another in a circuit-oriented manner by means of a first and second element connecting device 20, 22. The capacitor elements 10 are arranged next to one another in a matrix-like manner here, cf. also FIG. 4.

The first and second element connecting device 20, 22 of this exemplary embodiment in each case has a first main section 200 or second main section 220 arranged perpendicular to the normal direction N. These two main sections are arranged directly adjacent to and electrically insulated from one another.

In this exemplary embodiment, there is a direct thermal contact between the first main section 200 of the first element connecting device 20 and the first cooling contact surface 300 of the cooling device. This is also understood to mean here that there is only an insulation device 7 between the first cooling contact surface 300 and the first main section, which insulation device is formed here as a plastic film or as a heat-conductive but electrically insulating solid. It is decisive that no further, particularly heat-spreading, metallic intermediate layer is arranged here.

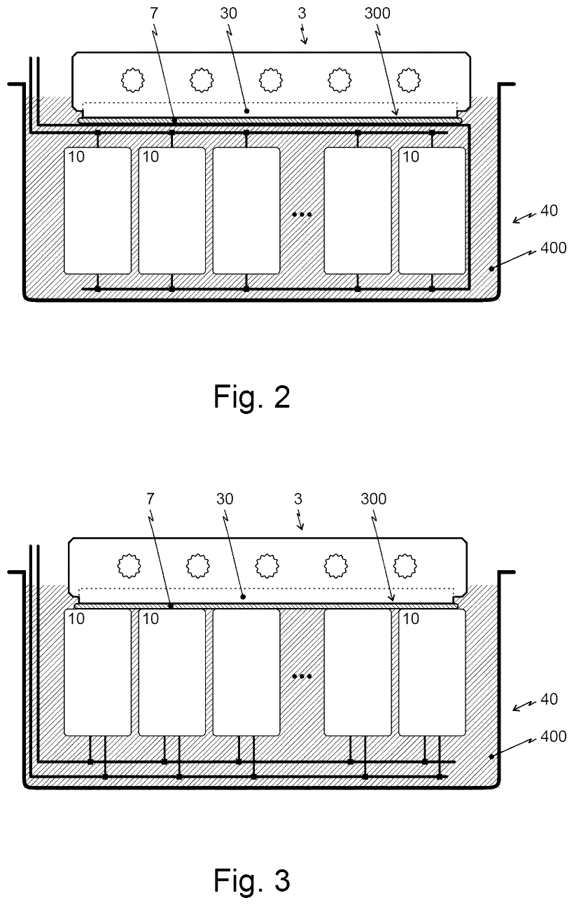

The entire capacitor device 1 and parts of the cooling device 3, cf. FIG. 2, are arranged here in a first partial housing 40 of the system.

A second cooling contact surface 320 of the cooling device 3, which is opposite the first, is in thermal contact with the power switching equipment 5. To this end, the power switching equipment, which is constructed as an unhoused power semiconductor module 5 here, is arranged directly on the second cooling contact surface 320. According to standard practice in the art, a thermal paste can also be arranged between the power switching equipment 5 and the second cooling contact surface 320.

The power switching equipment 5 is connected to the control switching equipment 6 by means of internal contact elements 52. This control switching equipment 6 is designed as a standard printed circuit board in the art and is used for activating the power switching equipment 5 and receives the associated control signal via a plug-in connection (not illustrated) with a superordinate controller, particularly a vehicle controller, if the power electronic system is part of a drivetrain of an electric vehicle.

A second partial housing 42, which interacts with the first partial housing 40, covers the power switching equipment 5 and the control switching equipment 6. This second partial housing 42 has bushings 420 for load terminal components 50 and plug-in connections for control signals, which are likewise not illustrated.

FIG. 2 shows a side view of this first embodiment. The cup-shaped first partial housing 40, the capacitor device arranged therein, the first and second element connecting devices 20, 22, the insulation device 7 and the cooling device are illustrated here. The insulation device 7, which is designed here as a heat-conductive but electrically insulating solid, is arranged exclusively between the first cooling contact surface 300 of this cooling device 3 and the first main section of the first element connecting device 20, cf. FIG. 1.

The cooling device 3 that is designed as a liquid cooling device has a cooling plate element 30 which is of flat design and the surface of which forms the first cooling contact surface 300. This cooling plate element 30 is formed in one piece with the cooling device 3.

The first partial housing is filled with an insulating agent 400 that is standard in the art for capacitor devices such that the capacitor device 1 is covered completely. This insulating agent 400 does not just reach up to the cooling device 3, but rather encloses the same up to a first height. This first height, when considered here in the normal direction, is greater than the thickness of the cooling plate element 30.

FIG. 3 shows a side view of a second embodiment of a power electronic system according to the invention. This differs essentially from that according to FIG. 2 in that the main sections 200, 220 of the first and second element connecting devices 20, 22 are arranged downstream of the capacitor device when viewed in the normal direction N. This means that when viewed in the normal direction N, no metallic body and rather only an insulation device 7 is arranged on the cooling contact surface 300 of the cooling device, as a result of which the capacitor elements are cooled directly by the cooling device, that is to say are in direct thermal contact with the same.

The cooling plate element 30, which is designed analogously to FIG. 2, covers more than 85% of each individual capacitor element 10 here. The arrangement of the insulating agent in the first partial housing corresponds to the embodiment according to FIG. 2 with respect to the cooling device in particular.

FIGS. 4 and 5 show three-dimensional sectional views of the first embodiment with a different number of components. FIG. 4 shows eight capacitor elements 10 of the capacitor device, which are arranged next to one another in a 2×4 matrix. Further illustrated are the first and a second element connecting device 20, 22, which also have module terminal components 202, 222 here. The first and a second element connecting device 20, 22 furthermore have sub-connection devices 206, 226 which reach through from the associated main sections between capacitor elements in the normal direction and contact the capacitor elements 10 on the underside thereof in a circuit-oriented manner.

Supplementary to FIG. 4, FIG. 5 also shows a cooling device 3 having a plurality of cooling plate elements 30 which are of flat design and the respective surfaces of which form first cooling contact surfaces 300. These cooling plate elements 30 are in turn formed in one piece with the cooling device 3.

Further illustrated by way of example are three power semiconductor modules 5 which are arranged on the second cooling contact surface of the cooling device. These power semiconductor modules 5, more precisely the DC voltage terminals thereof, are connected to the capacitor device 1 in a circuit-oriented manner by means of the module terminal components 202, 222. The capacitor device 1 with its capacitor elements is therefore used for supplying power to the power semiconductor modules 5.

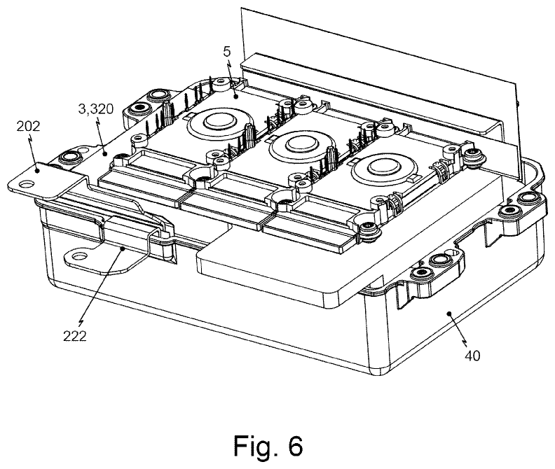

FIG. 6 shows a three-dimensional view of the first embodiment. In addition to FIG. 5, the first element connecting device 20 has an additional first terminal section 202 and the second element connecting device 22 has an additional second terminal section 222. These terminal sections 202, 222 are used for supplying power to all capacitor elements 10.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A power electronic system having a capacitor device and having a cooling device, wherein the cooling device has a first cooling contact surface with a normal direction (N), which is in direct thermal contact with the capacitor device, wherein the capacitor device has a first and a second element connecting device.

2. The power electronic system according to claim 1, wherein
the first element connecting device has a first main section arranged perpendicular to the normal direction (N) and preferably the second element connecting device also has a second main section arranged perpendicular to the normal direction (N), preferably directly adjacent to the first.

3. The power electronic system according to claim 1, wherein
the cooling device has a cooling plate element which is preferably of flat design and the surface of which forms the first cooling contact surface.

4. The power electronic system according to claim 3, wherein
the cooling plate element is formed in one piece with the cooling device.

5. The power electronic system according to claim 1, wherein
the capacitor device has a plurality of capacitor elements which are preferably arranged next to one another, preferably in a matrix-like manner, and which are connected in a circuit-oriented manner by means of the first and second element connecting devices.

6. The power electronic system according to claim 5, wherein
the first and preferably also the second main section is arranged between the first cooling contact surface and the capacitor elements.

7. The power electronic system according to claim 6, wherein
an insulation device, which is preferably formed flat, is arranged, preferably exclusively, for electrical insulation between the first element connecting device and the first cooling contact surface.

8. The power electronic system according to claim 2, wherein
the first cooling contact surface covers at least more than 70%, preferably more than 80% and in particular preferably more than 90% of the first main section.

9. The power electronic system according to claim 5, wherein
an insulation device, which is preferably formed flat, is arranged, preferably exclusively, for electrical insulation between the capacitor elements and the first cooling contact surface.

10. The power electronic system according to claim 9, wherein
the cooling plate element covers more than 70%, preferably more than 80% and in particular preferably more than 90% of each individual capacitor element.

11. The power electronic system according to claim 1, wherein
the capacitor device and the cooling device are arranged in a cup-shaped first partial housing.

12. The power electronic system according to claim 11, wherein
the cup-shaped first partial housing is filled with an insulating agent until it reaches the cooling device and covers the capacitor device completely.

13. The power electronic system according to claim 12, wherein
the cooling device is arranged up to a first height in the insulating agent.

14. The power electronic system according to claim 3, wherein
the first height is greater than the thickness of the cooling plate element.

15. The power electronic system according to claim 1, wherein
the first element connecting device has an additional first terminal section and the second element connecting device has an additional second terminal section and these terminal sections are designed for supplying power to all capacitor elements.

16. The power electronic system according to claim 1, wherein
the first element connecting device has an additional first module section and the second element connecting device has an additional second module section and these module sections are designed for supplying power to a power semiconductor module from the capacitor elements.

17. The power electronic system according to claim 1, wherein
a power semiconductor module is arranged on a second cooling contact surface that is parallel to the first.
